(19) United States
(12) Patent Application Publication
(10) Pub. No.: US 2017/0207157 A1
(43) Pub. Date: Jul. 20, 2017

(54) METHOD FOR MANUFACTURING SEMICONDUCTOR PACKAGE, AND SEMICONDUCTOR PACKAGE

(71) Applicant: J-DEVICES CORPORATION, Usuki-Shi (JP)

(72) Inventors: Kiyoaki HASHIMOTO, Kanagawa (JP); Yuko YAMAMOTO, Ishikawa (JP)

(21) Appl. No.: 15/375,241

(22) Filed: Dec. 12, 2016

(30) Foreign Application Priority Data
Jan. 15, 2016 (JP) 2016-005971

(51) Int. Cl. H01L 23/498; H01L 23/00; H01L 21/48

(52) U.S. Cl. CPC H01L 23/49827; H01L 23/49816; H01L 23/49838; H01L 21/486; H01L 24/30; H01L 24/27; H01L 21/4853

(57) ABSTRACT

A method for manufacturing a semiconductor package includes: forming an insulating layer on a support plate; forming a via in the insulating layer; locating a semiconductor device on the insulating layer such that an electrode of the semiconductor device is on the via; removing the support plate; forming a seed layer on a surface of the insulating layer opposite to the semiconductor device, in the via, and on a surface of the electrode of the semiconductor device; and forming a metal layer in the via.

### CROSS REFERENCE TO RELATED APPLICATIONS

This application is based upon and claims the benefit of priority from the prior Japanese Patent Application No. 2016-005971 filed on Jan. 15, 2016, the entire contents of which are incorporated herein by reference.

### FIELD

The present invention relates to a method for manufacturing a semiconductor package including lines formed by plating on a semiconductor device, and such a semiconductor package.

### BACKGROUND

In a production process of a substrate including a build-in active device such as an IC or an LSI, a via is generally formed by laser processing. In this case, in order to prevent the device from being damaged, an under barrier metal (UBM) (e.g., formed of copper) is formed on an aluminum pad on the device, and a via is formed in an insulating layer formed on the under barrier metal. Japanese Laid-Open Patent Publication No. 2013-30593 (United States Patent Application Publication No. 2013/0026650 A1) discloses formation of such a via.

Japanese Laid-Open Patent Publication No. 2013-30593 (United States Patent Application Publication No. 2013/0026650 A1) (see, for example, FIG. 7 of this publication) discloses a structure including a semiconductor device, electrode pads (corresponding to the above-described under barrier metal) adjacent to, and below, the semiconductor device, and an organic substrate (corresponding to the above-described insulating layer) adjacent to, and below, the electrode pad. The organic substrate has vias formed therein.

In order to form the vias in the organic substrate to realize such a structure, laser light needs to be directed from below the organic substrate toward the semiconductor device. The under barrier metal (in Japanese Laid-Open Patent Publication No. 2013-30593 (United States Patent Application Publication No. 2013/0026650 A1), Cu electrode pads) needs to be located below the semiconductor device in advance in order to prevent the semiconductor device from being irradiated with the laser light.

### SUMMARY

A method for manufacturing a semiconductor package in an embodiment according to the present invention includes forming an insulating layer on a support plate; forming a via in the insulating layer; locating a semiconductor device on the insulating layer such that an electrode of the semiconductor device is on the via; removing the support plate; forming a seed layer on a surface of the insulating layer opposite to the semiconductor device, in the via, and on a surface of the electrode of the semiconductor device; and forming a metal layer in the via.

A semiconductor package in an embodiment according to the present invention includes a semiconductor device having an electrode exposed on a surface thereof; an adhesive layer located on a surface of the semiconductor device; an insulating layer located on the adhesive layer; a via running through the adhesive layer and the insulating layer to expose the electrode; a seed layer provided on a surface of the insulating layer and on an inner wall of the via to be in contact with the electrode; a metal layer in contact with the seed layer to bury the via; and a solder ball in contact with the metal layer.

### BRIEF DESCRIPTION OF DRAWINGS

FIG. 1A is a cross-sectional view of a support plate and a first adhesive layer;

FIG. 1B is a cross-sectional view of the support plate, the first adhesive layer, and a second adhesive layer;

FIG. 1C is a cross-sectional view showing a state where vias are formed in the structure shown in FIG. 1B;

FIG. 2A is a cross-sectional view showing a state where a semiconductor device is located on the structure shown in FIG. 1C and a resin sealing material layer is formed thereon;

FIG. 2B is a cross-sectional view showing a state where the support plate and the first adhesive layer are removed from the structure shown in FIG. 2A;

FIG. 3A is a cross-sectional view showing a state where the structure shown in FIG. 2B is put upside down;

FIG. 3B is a cross-sectional view showing a state where a seed layer is formed on the structure shown in FIG. 3A;

FIG. 4A is a cross-sectional view showing a state where a metal layer is formed on the structure shown in FIG. 3B;

FIG. 4B is a cross-sectional view of a semiconductor package including a solder resist layer and solder balls mounted on the structure shown in FIG. 4A;

FIG. 5A is a perspective view of the structure shown in FIG. 4A;

FIG. 5B is a cross-sectional view of a structure having a via land connection, in which the vias are formed in the insulating layer by laser light directed thereto;

FIG. 6A is a cross-sectional view showing a structure in which the vias are formed in the insulating layer by laser light directed thereto in order to connect leads;

FIG. 6B is a perspective view of the structure shown in FIG. 6A;

FIG. 7A is a cross-sectional view of a semiconductor package in modification 1;

FIG. 7B is a cross-sectional view of a semiconductor package in modification 5;

FIG. 8 is a cross-sectional view of a semiconductor package in modification 2; FIG. 9 is a cross-sectional view of a semiconductor package in modification 3; and

FIG. 10 is a cross-sectional view of a semiconductor package in modification 4.

### DESCRIPTION OF EMBODIMENTS

Hereinafter, embodiments of the present invention will be described with reference to the drawings and the like. The present invention may be carried out in various other embodiments, and should not be construed as being limited to any of the following embodiments. In the drawings, components may be shown schematically regarding the width, thickness, shape and the like, instead of being shown in accordance with the actual sizes, for the sake of clear illustration. The drawings are merely examples and do not limit the interpretations of the present invention in any way. In the specification and the drawings, components that are substantially the same as those described or shown previously bear the identical reference signs thereto, and detailed descriptions thereof may be omitted when necessary.

In this specification, an expression that a component or area is “on” or “below” another component or area encompasses a case where such a component or area is in contact with the other component or area and also a case where such a component or area is out of contact with the another component or area, namely, a case where still another component or area is provided between such a component or area and the another component or area, unless otherwise specified.

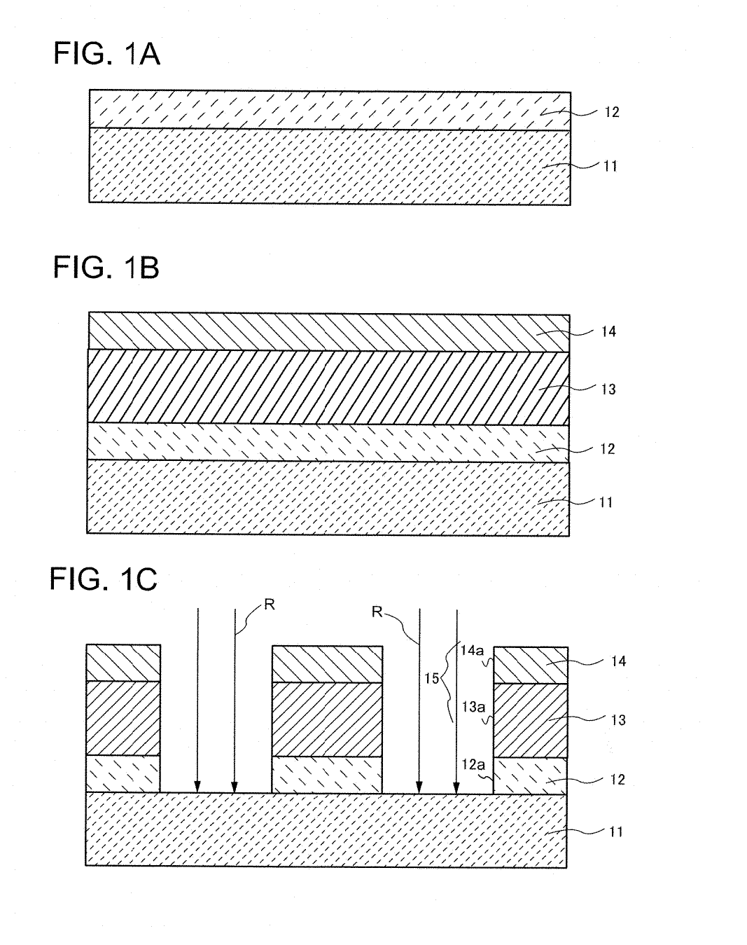

With reference to FIG. 1A through FIG. 4B, a method for manufacturing a semiconductor package 10 in this embodiment will be described. FIG. 1A is a cross-sectional view of a support plate 11 and a first adhesive layer 12. As shown in FIG. 1A, the first adhesive layer 12 is formed on the support plate 11.

The first adhesive layer 12 is capable of bonding the support plate 11 and an insulating layer 13 (described below) to each other and is peelable by heat or UV light. The first adhesive layer 12 is formed of, for example, a thermally peelable foaming tacky material. In the case where the support plate 11 is formed of, for example, glass, UV (ultraviolet) light passes the support plate 11 to be directed toward the first adhesive layer 12, and thus the support plate 11 is peeled off.

FIG. 1B is a cross-sectional view of the support plate 11, the first adhesive layer 12, the insulating layer 13, and a second adhesive layer 14. As shown in FIG. 1B, the insulating layer 13 is formed on the first adhesive layer 12, and the second adhesive layer 14 is formed on the insulating layer 13. Thus, the insulating layer 13 is provided on the support plate 11. The insulating layer 13 may be formed of, for example, a resin containing a filler. For example, a polyimide resin or an epoxy resin containing a filler is usable. (The material of the insulating layer 13 is not limited to any of these.)

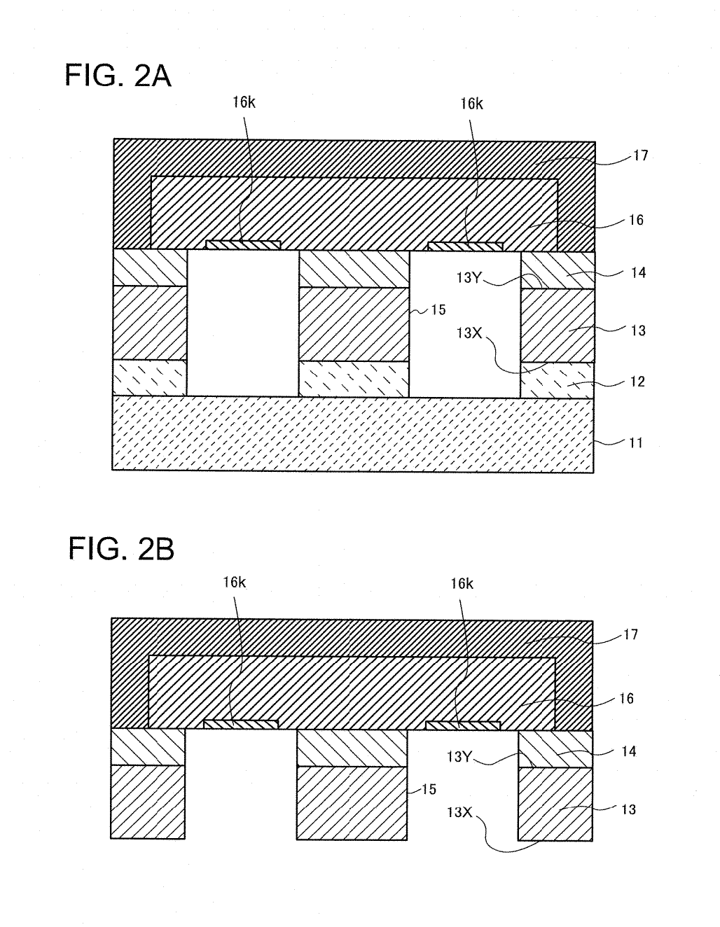

The second adhesive layer 14 is capable of bonding the insulating layer 13 in the state of having holes 13a (see FIG. 1C; described below) formed therein and a semiconductor device 16 (see FIG. 2A) to each other. At a B stage before the second adhesive layer 14 is heated and thus cured (intermediate stage in a reaction on which the material is softened by heat and thus is expanded but is not completely melted or dissolved even when contacting a certain type of liquid), the second adhesive layer 14 is adhesive to Si or an Si compound used to form the semiconductor device 16. In a heating and curing step, the second adhesive layer 14 is capable of retaining the shape of one or a plurality of vias 15.

The second adhesive layer 14 is formed of, for example, an adhesive of polyimide. In the case where the insulating layer 13 contains a filler as described above, the second adhesive layer 14 needs to be formed of polyimide or the like replacing a wafer-coating material in order to alleviate the stress or in order to suppress a bit error from being caused by an a ray generated from the filler. At the B stage, the second adhesive layer 14 flows into the vias 15 when the temperature is raised to a certain degree. In order to suppress this, the second adhesive layer 14 needs to be formed of a material that retains the shape of the vias 15 to a predetermined temperature.

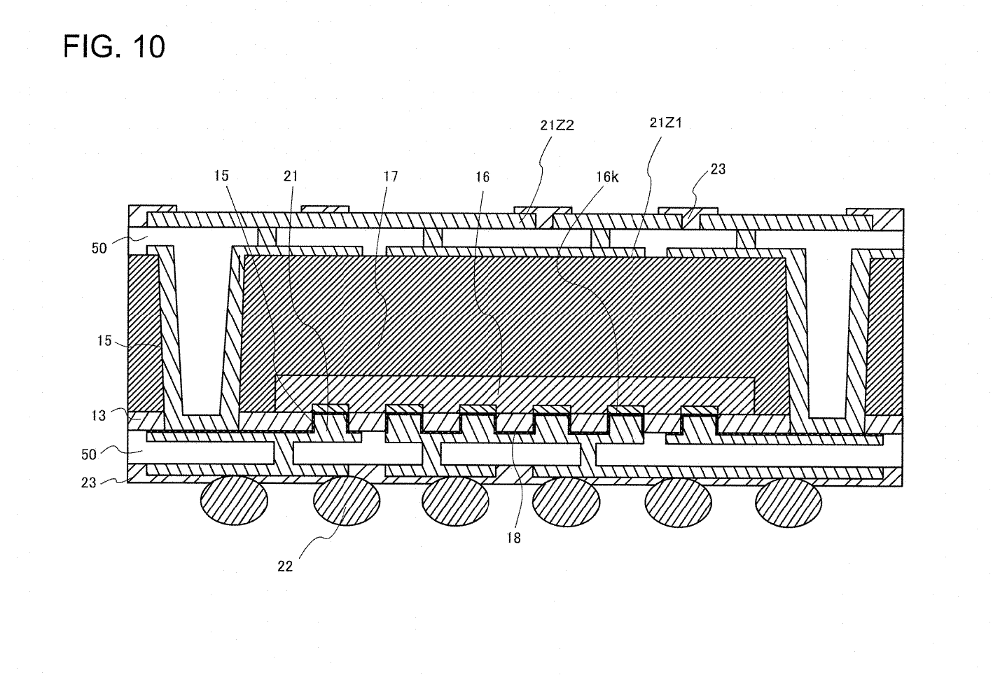

FIG. 10 is a cross-sectional view showing a state where the vias 15 are formed in the structure shown in FIG. 1B. As shown in FIG. 1C, the vias 15 are formed in the insulating layer 13 and the second adhesive layer 14. The vias 15 (through-holes; openings) each include the hole 13a formed in the insulating layer 13 and a hole 14a formed in the second adhesive layer 14. The vias 15 each include a hole 12a formed in the first adhesive layer 12. However, the first adhesive layer 12 is removed together with the support plate 11 in a later stage, and thus the vias 15 are not necessary for a semiconductor package 10 as a finished product.

The vias 15 may be formed at least by any of laser processing (processing by use of laser light R) or mechanical processing such as drill bit processing, press punching or the like. In this example, the vias 15 are formed by laser processing, and the laser light R may be, for example, laser light usable for thermal processing, CO₂ laser light or UV-YAG laser light (UV-type light generated by a solid-state laser). For the formation of the vias 15, holes need to be formed in the support plate 11. This causes no problem because the support plate 11 is removed in a later stage.

The insulating layer 13 may be formed of a photosensitive resin so that the vias 15 are formed by expose and development. This method may be performed by plasma ashing by use of a mask, or by forming a copper resist and performing plasma processing only on a processing target by use of a mask.

FIG. 2A is a cross-sectional view showing a state where the semiconductor device 16 is located on the structure shown in FIG. 10 and a resin sealing material layer 17 is formed thereon. Now, a surface of the insulating layer 13 facing the first adhesive layer 12 is referred to as a “first surface 13X”, and a surface of the insulating layer 13 facing the second adhesive layer 14 is referred to as a “second surface 13Y”. As shown in FIG. 2A, the semiconductor device 16 is located on the second adhesive layer 14, which is located on the second surface 13Y of the insulating layer 13, such that electrodes 16k of the semiconductor device 16 are located on the vias 15 formed as shown in FIG. 10. In this manner, the semiconductor device 16 is mounted on the insulating layer 13 having the vias 15 with direct alignment, and then the resultant structure is sealed with the resin sealing material layer 17.

As the sealing is made by use of the resin sealing material layer 17, the positional precision is improved between the vias 15 and the electrodes 16k. The electrodes 16k are each, for example, an aluminum pad formed of aluminum.

FIG. 2B is a cross-sectional view showing a state where the support plate 11 and the first adhesive layer 12 are removed from the structure shown in FIG. 2A. After the state shown in FIG. 2A is obtained, the support plate 11 is removed. For example, the support plate 11 is formed of glass, and UV light is directed toward the support plate 11. Thus, the support plate 11 is peeled off at the first adhesive layer 12.

As can be seen from the above, the laser light directed to form the vias 15 is received by the support plate 11, which is not necessary for the structure of the semiconductor package 10. Therefore, the under barrier metal, which is conventionally provided to receive laser light directed to form the vias, is not needed.

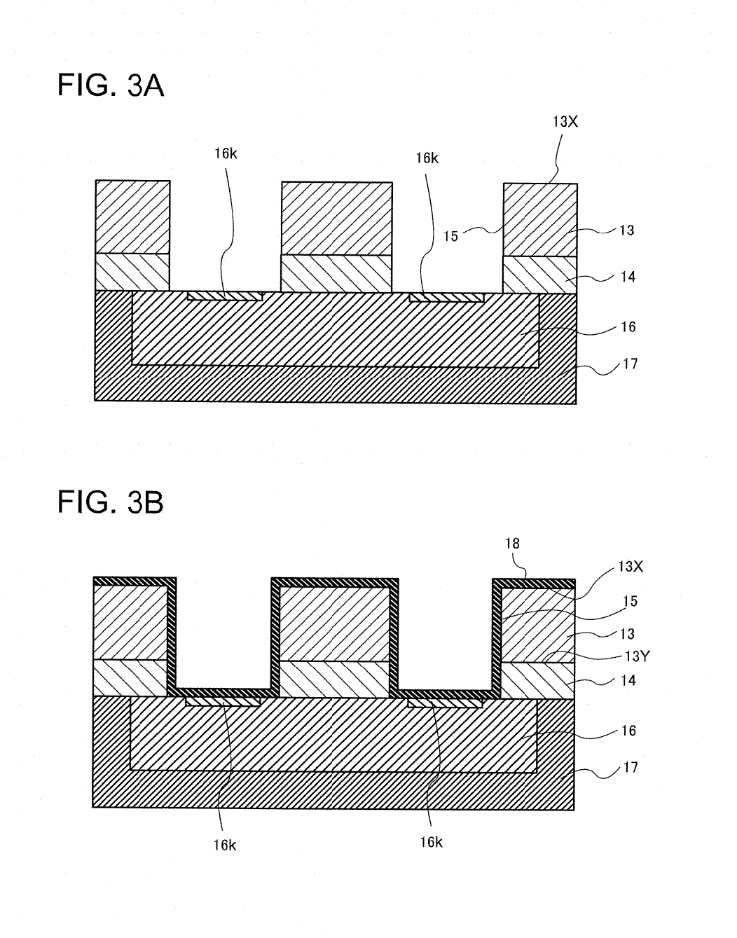

FIG. 3A is a cross-sectional view showing a state where the structure shown in FIG. 2B is put upside down. In the state shown in FIG. 3A, a total thickness of the second adhesive layer 14 and the insulating layer 13 is, for example, about 15 μm.

FIG. 3B is a cross-sectional view showing a state where a seed layer 18 is formed on the structure shown in FIG. 3A. As shown in FIG. 3B, the seed layer 18 is formed, from the side on which the vias 15 are opened, on the first surface 13X of the insulating layer 13 (surface of the insulating layer 13 opposite to the semiconductor device 16), in the vias 15 and on the electrodes 16k of the semiconductor device 16.

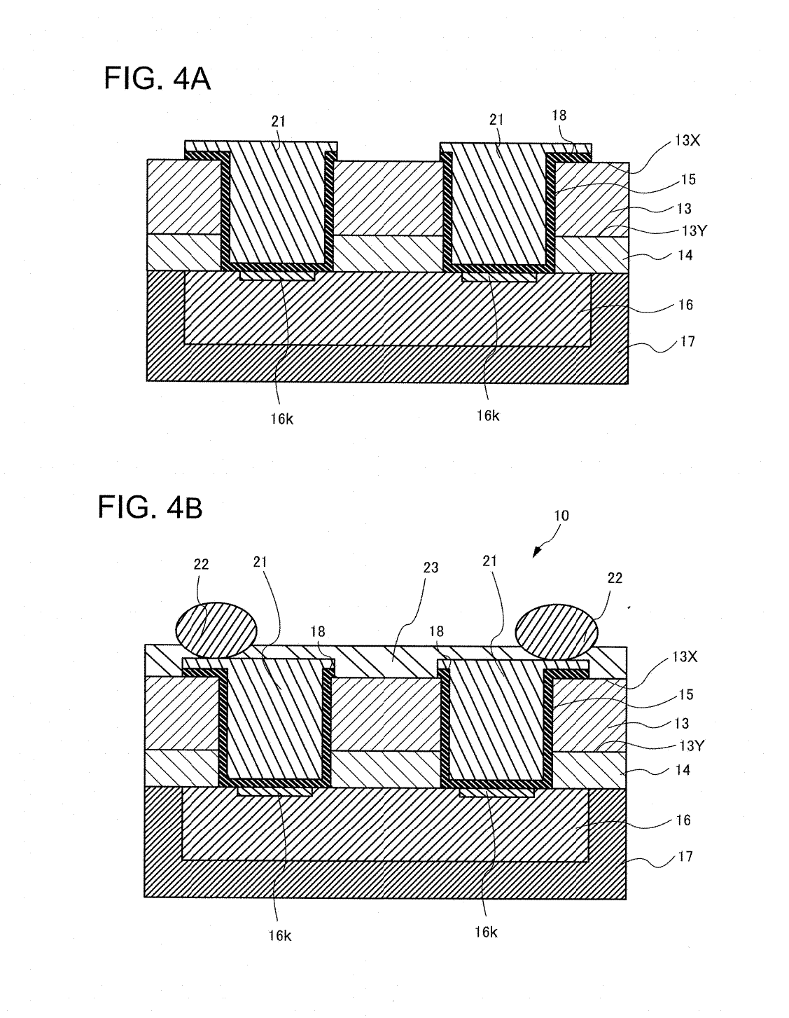

FIG. 4A is a cross-sectional view showing a state where a metal layer 21 is formed on the structure shown in FIG. 3B. As shown in FIG. 4A, the metal layer 21 is formed in the vias 15.

In this embodiment, the seed layer 18 is formed by sputtering of Ti and Cu. The metal layer 21 is formed by, for example, electrolytic plating. In this case, the metal layer 21 is formed with no special surface treatment made on the electrodes 16 of the semiconductor device 16 (e.g., without forming an under barrier metal (UBM) conventionally formed). For forming the seed layer 18, Ta may be used instead of Ti. Alternatively, the seed layer 18 may be formed of a barrier metal such as TiW, TiN or the like. The material of the seed layer 18 may be changed appropriately.

If an under barrier metal is to be formed as with the above-described conventional art, for example, polyimide is applied to the semiconductor device 16 while openings are formed at positions corresponding to the electrodes 16k. A Ti/Cu seed layer is formed thereon to perform Cu plating, and seed etching is performed to form the under barrier metal. As can be seen, formation of an under barrier metal requires a plurality of steps and is time-consuming. This is avoided by the method in this embodiment.

Instead of the electrolytic plating being performed, the electrodes 16k of the semiconductor device 16 may be zincate-treated, and then the seed layer 181 may be formed by electroless plating. In this case, the seed layer 18 is formed by electroless plating, which costs less.

As described above, the seed layer 18 is formed by sputtering or electroless plating and is used to form the metal layer 21 by electrolytic plating or electroless plating. After this, a part of the seed layer 18 that is not used for lines is removed by etching.

FIG. 4B is a cross-sectional view of the semiconductor package 10 including a solder resist layer 23 and a plurality of solder balls 22 provided on the structure shown in FIG. 4A. As shown in FIG. 4B, a solder resist is applied to cover the metal layer 21 to form the solder resist layer 23. Then, the solder balls 22 are mounted in contact with the metal layer 21. Thus, the semiconductor package 10 is produced.

The semiconductor device 16 produced in this manner includes, sequentially from the side of the semiconductor device 16, the semiconductor device 16, the second adhesive layer 14 formed on the semiconductor device 16, the insulating layer 13 formed on the second adhesive layer 14, the vias 15 running straight from top surfaces of the electrodes 16k of the semiconductor to a top surface of the insulating layer 13 through the second adhesive layer 14, the seed layer 18 formed in the vias 15, the metal layer 21 formed inner to the seed layer 18, and the solder balls 22 located in contact with the metal layer 21. The metal layer 21 is formed by plating in this example, but may be formed in any other appropriate method.

In other words, the semiconductor device 10 produced in the above-described manner includes, sequentially from the side of the semiconductor device 16, the semiconductor device 16 having the electrodes 16k exposed on a surface thereof, the second adhesive layer 14 (adhesive layer) located on a surface of the semiconductor device 16, the insulating layer 13 located on the second adhesive layer 14, the vias 15 running through the second adhesive layer 14 and the insulating layer 13 to expose the electrodes 16k, the seed layer 18 provided on a surface of the insulating layer 13 and along an inner wall of each of the vias 15 to contact the electrodes 16k, the metal layer 21 located in contact with the seed layer 18 to bury the vias 15, and the solder balls 22 in contact with the metal layer 21. The seed layer 18 and the metal layer 21 in contact with the seed layer 18 may be collectively referred to as “buried electrodes”.

As described above, the vias 15 are formed to run straight in a thickness direction of the semiconductor device 16 from the top surfaces of the electrodes 16k of the semiconductor device 16 to the top surface of the insulating layer 13 through the second adhesive layer 14. The electrodes 16k of the semiconductor device 16 and the seed layer 18 are in contact with each other. With the method in this embodiment, the under barrier metal is not needed, and therefore, the vias 15 may be formed to have a larger planar size than that of the electrodes 16k respectively.

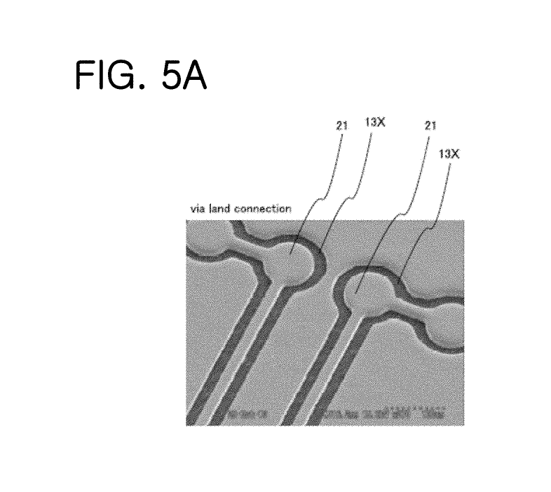

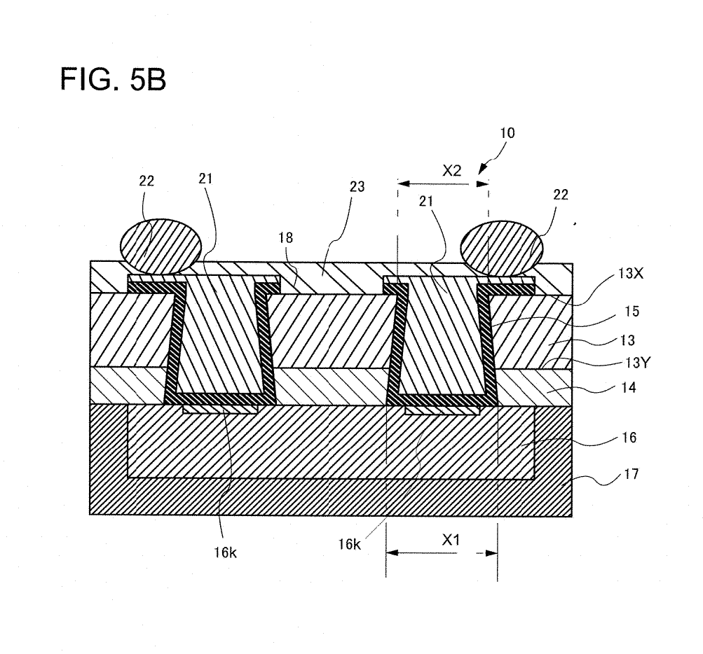

By contrast, with the conventional structure, the under barrier metal is formed on the semiconductor device 16. Therefore, holes may run straight from a top surface of the under barrier metal to a top surface of the insulating layer 13. However, below the top surface of the under barrier metal, the under barrier metal has a larger planar size than that of the vias. Thus, a space having a planar size different from that of the vias needs to be saved for the under barrier metal. As a result, the holes do not run straight from top surfaces of the electrodes 16k of the semiconductor device 16 to the top surface of the insulating layer 13. Since the under barrier metal is provided between the electrodes of the semiconductor device and a seed layer, the electrodes of the semiconductor device and the seed layer are not in contact with each other. The term “straight” mentioned above may encompass a case where as shown in FIG. 4B, the holes are formed in the thickness direction of the semiconductor device 16, and also a case where as shown in FIG. 5B, the holes are inclined with respect to the thickness direction of the semiconductor device 16.

With the conventional art, an alignment margin needs to be saved in consideration of the variance in the position or size of the semiconductor device 16, the variance in the position or size of the under barrier metal to be formed on the semiconductor device 16, and the variance in the position or size of the vias to be formed in the insulating layer located on the under barrier layer. By contrast, with the method for manufacturing the semiconductor package 10 in this embodiment, it is not necessary to consider the variance in the position or size of the under barrier metal. Therefore, the vias may be formed to be larger, which increases the degree of freedom of design.

With the conventional art, the vias need to be formed by use of laser light such that the electrodes of the semiconductor device have a larger planar size than that of the vias. By contrast, with the method for manufacturing the semiconductor package 10 in this embodiment, a part of a resin (around of the electrodes) in the semiconductor device 16 is not irradiated with the laser light R. Therefore, the vias 15 may be formed such that the electrodes 16k of the semiconductor device 16 have a smaller planar size than that of the vias 15. Thus, small electrodes may be used as the electrodes 16k with no consideration of the size of the vias 15, and thus the pitch of the electrodes 16k may be decreased.

With the conventional art, there is a risk that in the case where the laser light R is positionally shifted from the under barrier metal during the formation of the vias, the semiconductor device 16 may be destroyed. In this embodiment, there is no such risk.

With the conventional art, a height of a portion of the semiconductor package on the semiconductor device (total height of the seed layer and metal layer) is 80 μm. The structure of this embodiment decreases such a height to 50 μm, and it is theoretically considered that the height may be decreased to 40 μm.

FIG. 5A is a perspective view of the structure shown in FIG. 4A. As shown in FIG. 5A, the metal layer 21 is formed in an area enclosed by the first surface 13X of the insulating layer 13. Below the metal layer 21, the via 15 is confined.

FIG. 5B is a cross-sectional view of a structure having a via land connection, in which the vias 15 are formed in the insulating layer 13 by laser light directed thereto. In the case where the vias 15 are formed by laser light, the vias 15 are tapered so as to have a planar size decreasing from the side of the semiconductor device 16 toward the side of the insulating layer 13. Namely, the holes in the insulating layer 13 and the second adhesive layer 14 have a larger planar size at a position closer to the side that is irradiated with the laser light. The side irradiated with the laser light corresponds to the side on which the semiconductor device 16 is located. As shown in FIG. 5B, width X1 of the vias 15 in the insulating layer 13 and the second adhesive layer 14 on the side closer to the semiconductor device 16 is larger than width X2 of the vias 15 on the side farther from the semiconductor device 16.

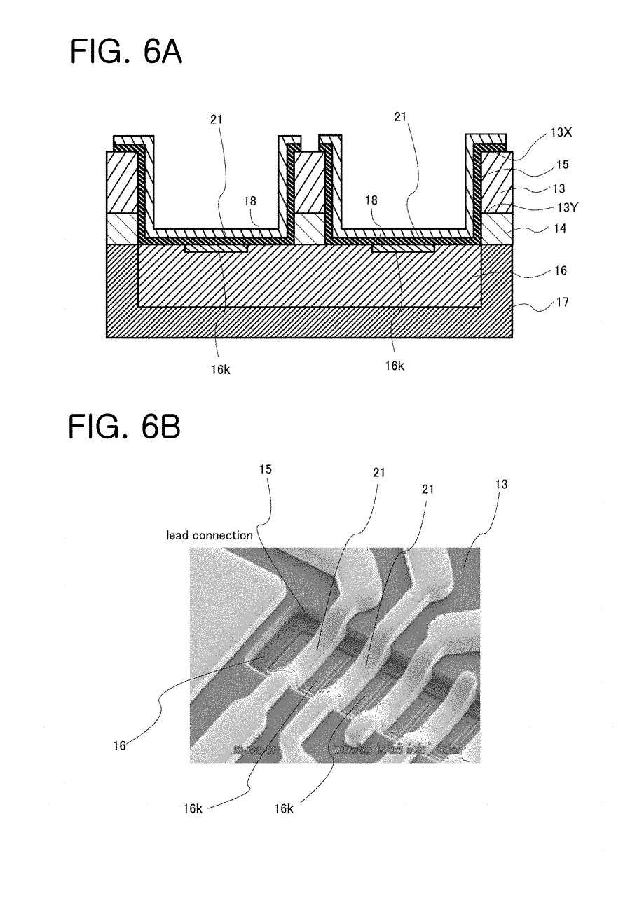

FIG. 6A is a cross-sectional view showing a structure in which the vias 15 are formed in the insulating layer 13 by laser light directed thereto in order to connect leads. FIG. 6B is a perspective view of the structure shown in FIG. 6A. For connecting the leads, the vias 15 formed in the insulating layer 13 have a large planar size and thus the entirety of the inner wall of each of the vias 15 is not plated with the metal layer 21. Namely, the vias 15 are not filled with the metal layer 21, but the metal layer 21 has a predetermined thickness along the shape of the vias 15. Even such a structure provides substantially the same effect as described above with reference to FIG. 1A through FIG. 5B.

With the method for manufacturing the semiconductor package 10 in this embodiment, the vias 15 may be formed such that the planar size of the electrodes 16k of the semiconductor device 16 is smaller than that of the vias 15. Therefore, a lengthy via 15 exposing a plurality of electrodes 16k as shown in FIG. 6B may be formed, instead of small openings each overlapping a part of the corresponding electrode 16k.

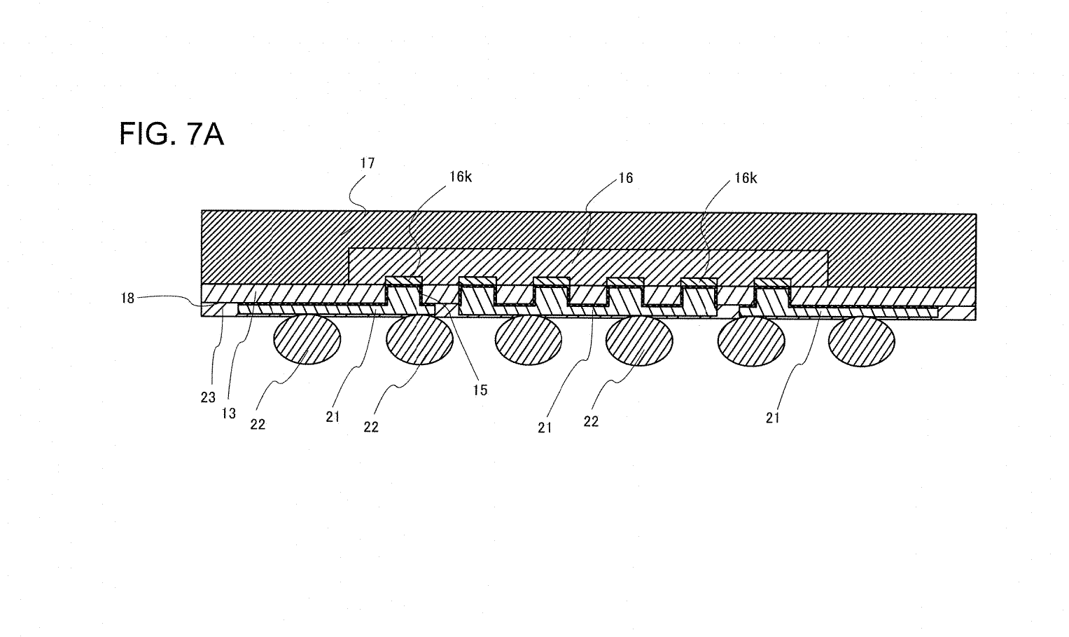

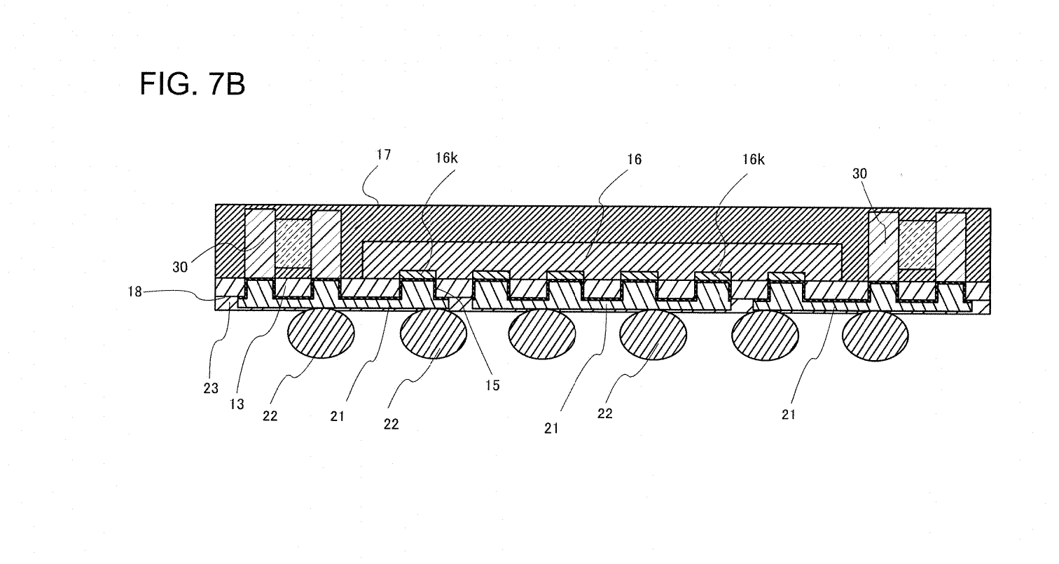

FIG. 7A is a cross-sectional view of a semiconductor package 10 in modification 1 of this embodiment. The semiconductor package 10 shown in FIG. 7A has substantially the same structure as that shown in FIG. 4B. The semiconductor package 10 shown in FIG. 7A is obtained as a result of the semiconductor device 10 shown in FIG. 4B being put upside down. The semiconductor device 16 is covered with the resin sealing material layer 17. The insulating layer 13 is formed below the semiconductor device 16 while the second adhesive layer 14 (not shown) is provided between the insulating layer 13 and the semiconductor device 16. The solder resist layer 23 is located below the insulating layer 13. Below the electrodes 16k of the semiconductor device 16, the vias 15 are formed in the insulating layer 13. The metal layer 21 is formed in the vias 15 and below the insulating layer 13. The solder resist layer 23 is formed, and the solder balls 22 are located below the metal layer 21.

With such a structure also, in the case where the vias 15 are formed by laser light, the vias 15 are tapered so as to have a planar size decreasing from the side of the semiconductor device 16 toward the side of the insulating layer 13.

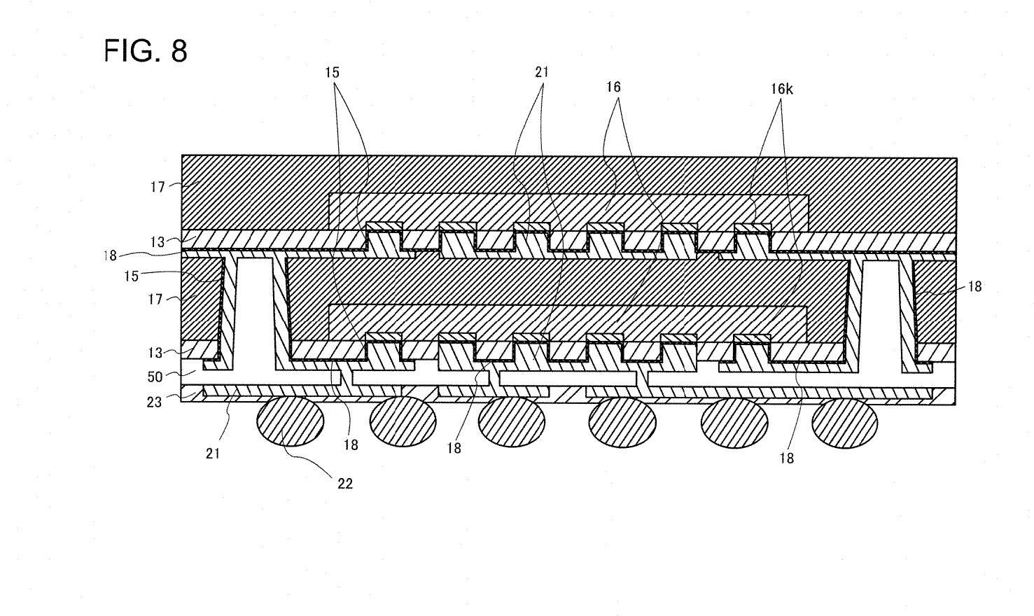

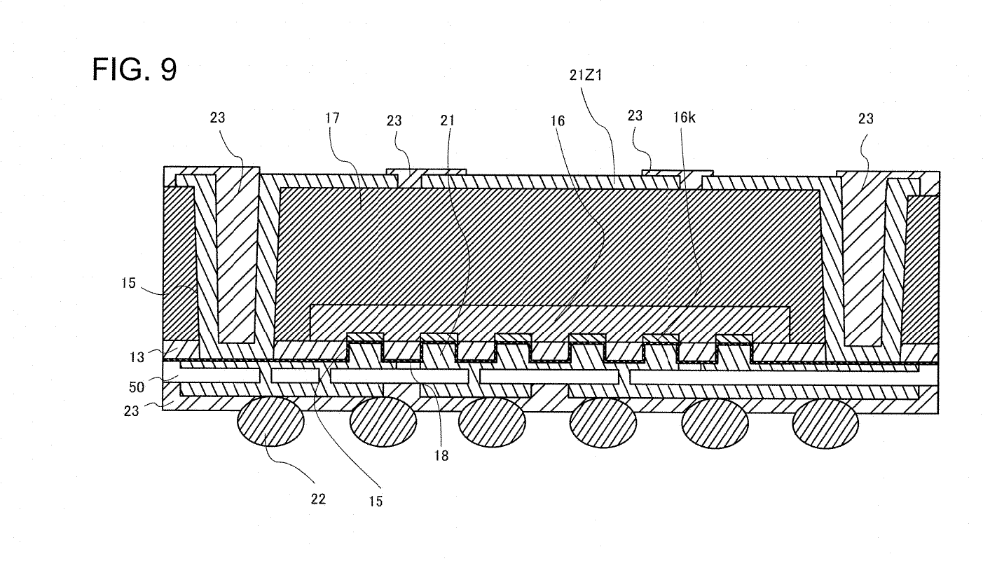

FIG. 8 is a cross-sectional view of a semiconductor package 10 in modification 2 of this embodiment. In this modification, the semiconductor package 10 includes two semiconductor devices 16 arrayed in an up-down direction. The insulating layer 13 is formed below each of the semiconductor devices 16 while the second adhesive layer 14 (not shown) is provided between the insulating layer 13 and the semiconductor device 16. The vias 15 are formed in each of the insulating layers 13. The metal layer 21 is formed in the vias 15 and below each of the insulating layers 13. Below the lower metal layer 21, the solder resist layer 23 is formed and the plurality of solder balls 22 are located. An insulating layer 50 is located between the lower insulating layer 13 and the solder resist layer 23.

In this modification, vias 15 are formed also in the resin sealing material layers 17. Unlike in FIG. 7A, the vias 15 formed in the resin sealing material layers 17 have a planar size decreasing from the side of the lower insulating layer 13 toward the side of the lower semiconductor device 16 (decreasing upward).

FIG. 9 is a cross-sectional view of a semiconductor package 10 in modification 3 of this embodiment. This modification is for a lower stage of a package-on-package structure. The package-on-package structure includes a semiconductor package 10 and another semiconductor package 10 provided on the first semiconductor package 10. This modification is directed to the lower semiconductor package 10. As shown in FIG. 9, a connection terminal portion 21Z1 is provided on the semiconductor device 16 so as to allow another semiconductor package to be mounted on the semiconductor package 10 shown in FIG. 9.

In this modification also, the insulating layer 13 is formed below the semiconductor device 16. The plurality of vias 15 are formed in the insulating layer 13. The metal layer 21 is formed in the vias 15 and below the insulating layer 13. In this modification, the metal layer 21 is branched, and the insulating layer 50 is formed between the branches of the metal layer 21. Below the metal layer 21, the solder resist layer 23 is formed and the plurality of solder balls 22 are located.

Like in FIG. 8, the vias 15 are formed also in the resin sealing material layers 17. Unlike in FIG. 8, the vias 15 formed in the resin sealing material layers 17 have a planar size decreasing from the side of the semiconductor device 16 toward the side of the insulating layer 13 (decreasing downward). Unlike in FIG. 8, the solder resist layer 23 is formed above the semiconductor device 16 as well as below the semiconductor device 16. The solder resist layer 23 also fills the vias 15 formed in the resin sealing material layers 17. With this structure, another semiconductor package prepared to be located on the semiconductor device 16 is allowed to be located on an area of the connection terminal portion 21Z1 above the semiconductor device 16, the area excluding areas located in the vias 15.

FIG. 10 is a cross-sectional view of a semiconductor package 10 in modification 4. In this modification, the connection terminal portion 21Z1 (line layer) is located on the semiconductor device 16, and a connection terminal portion 21Z2 is located on the connection terminal portion 21Z1. This allows another connection terminal portion to be located on a top surface of the connection terminal portion 21Z2 including areas above the vias 15 formed in the resin sealing material layer 17.

In this modification also, the insulating layer 13 is formed below the semiconductor device 16. The plurality of vias 15 are formed in the insulating layer 13. The metal layer 21 is formed in the vias 15 and below the insulating layer 13. In this modification also, the metal layer 21 is branched, and the insulating layer 50 is formed between the branches of the metal layer 21. Below the metal layer 21, the solder resist layer 23 is formed and the plurality of solder balls 22 are located.

Like in FIG. 8, the vias 15 are formed also in the resin sealing material layers 17. Unlike in FIG. 8, the vias 15 formed in the resin sealing material layers 17 have a planar size decreasing from the side of the semiconductor device 16 toward the side of the insulating layer 13 (decreasing downward). Unlike in FIG. 9, the insulating layer 50 is formed above the semiconductor device 16 as well as below the semiconductor device 16.

FIG. 7B is a cross-sectional view of a semiconductor package 10 in modification 5. As shown in FIG. 7B, passive elements 30 may be provided at positions where the electrodes 16k are to be located at ends, in a lateral direction, of the semiconductor device 16, namely, provided in place of the electrodes 16k. Each of the passive elements 30 is, for example, a capacitor, an inductor, a resistor or the like.

With any of the structures described in embodiment 1 and modifications 1 through 5, the vias 15 are formed in the insulating layer 13 provided above and/or below the semiconductor device 16 with no need to direct laser light in the state where an under barrier metal is provided at a position closer to the laser light than the semiconductor device 16 is (provided adjacent to the electrode 16k). The under barrier metal does not need to be provided to form the vias 15, and thus the production cost of the semiconductor package 10 is decreased. With the production of the semiconductor package 10, the vias are formed using a smaller number of components than with the conventional method.

The production method also solves the problem of the risk that the semiconductor device 16 may be damaged at the time of forming the vias 15, and improves the degree of freedom of design. The semiconductor package 10 may have a structure with a smaller electrode pad pitch when being combined with a certain structure of lead connection. For example, with the conventional method, the vias may be occasionally formed by photolithography by use of a photosensitive insulating material in the case of wafer level packaging. Use of photolithography for forming the vias has problems that, for example, the materials are costly and that the design is restricted by the restriction on the thickness of the insulating layer. For example, there is a restriction on the thickness of the insulating layer because of the problem of resolution in the development step and the problem of warp caused by residual stress. The method in this embodiment has an advantage of alleviating such restrictions on the design.

The insulating layer is allowed to be formed with a thickness desired from the point of view of the electrical characteristics, and also the materials are allowed to be selected more freely, and the warp is avoided although the thickness can be thin. This allows the thickness of the insulating layer 13 to be thicker than 15 μm, which is assumed in order to decrease the inter-layer capacitance.

Since a smaller number of types of materials are used to form the semiconductor package 10, the warp of the semiconductor package 10 is suppressed. Since the resin is sealed after the vias are formed or the semiconductor device 16 is die-attached, the positional shift between the vias 15 and the semiconductor device 16 is alleviated.

With the conventional method using the under barrier metal, the vias are holes closed at the bottom. Therefore, the resin remaining at the bottom of the vias is difficult to be removed after the laser light is directed. If a step called “desmear” of removing the resin from the bottom of the vias is not performed sufficiently, a foreign substance is held at a joint surface between the bottom and the metal layer, which may decline the reliability of the semiconductor package. By contrast, with the method in any of the embodiment and modifications 1 through 5, the resin does not remain easily when the support plate 11, at the bottom of the vias 15, irradiated with the laser light and the first adhesive layer 12 are removed. As a result, the reliability of the semiconductor package 10 is guaranteed.

1. A method for manufacturing a semiconductor package, comprising:
forming an insulating layer on a support plate;
forming a via in the insulating layer;
locating a semiconductor device on the insulating layer such that an electrode of the semiconductor device is on the via;
removing the support plate;
forming a seed layer on a surface of the insulating layer opposite to the semiconductor device, in the via, and on a surface of the electrode of the semiconductor device; and
forming a metal layer in the via.

2. The method for manufacturing a semiconductor package according to claim 1, wherein the support plate and the insulating layer are bonded to each other by a first adhesive layer peelable by heat or UV light.

3. The method for manufacturing a semiconductor package according to claim 1, wherein the insulating layer and the semiconductor device are bonded to each other by a second adhesive layer adhesive to the semiconductor device in a B stage before being heated and cured and capable of retaining a shape of the via in a heating and curing step.

4. The method for manufacturing a semiconductor package according to claim 2, wherein the insulating layer and the semiconductor device are bonded to each other by a second adhesive layer adhesive to the semiconductor device in a B stage before being heated and cured and capable of retaining a shape of the via in a heating and curing step.

5. The method for manufacturing a semiconductor package according to claim 1, wherein the via is formed at least by any of laser processing, drill bit processing, and press punching.

6. The method for manufacturing a semiconductor package according to claim 2, wherein the via is formed at least by any of laser processing, drill bit processing, and press punching.

7. The method for manufacturing a semiconductor package according to claim 3, wherein the via is formed at least by any of laser processing, drill bit processing, and press punching.

8. The method for manufacturing a semiconductor package according to claim 4, wherein the via is formed at least by any of laser processing, drill bit processing, and press punching.

9. The method for manufacturing a semiconductor package according to claim 1, wherein the insulating layer is formed of a photosensitive resin, and the via is formed by exposure and development.

10. The method for manufacturing a semiconductor package according to claim 2, wherein the insulating layer is formed of a photosensitive resin, and the via is formed by exposure and development.

11. The method for manufacturing a semiconductor package according to claim 3, wherein the insulating layer is formed of a photosensitive resin, and the via is formed by exposure and development.

12. The method for manufacturing a semiconductor package according to claim 4, wherein the insulating layer is formed of a photosensitive resin, and the via is formed by exposure and development.

13. The method for manufacturing a semiconductor package according to claim 1, wherein the seed layer is formed by sputtering, and the metal layer is formed by electrolytic plating.

14. The method for manufacturing a semiconductor package according to claim 1, wherein the electrode of the semiconductor device is zincate-treated, the seed layer is formed by electroless plating, and the metal layer is formed by electrolytic plating.

15. A semiconductor package, comprising:
a semiconductor device having an electrode exposed on a surface thereof;
an adhesive layer located on a surface of the semiconductor device;
an insulating layer located on the adhesive layer;
a via running through the adhesive layer and the insulating layer to expose the electrode;
a seed layer provided on a surface of the insulating layer and on an inner wall of the via to be in contact with the electrode;
a metal layer in contact with the seed layer to bury the via; and
a solder ball in contact with the metal layer.

16. The semiconductor package according to claim 15, wherein the via is tapered to have a planar size decreasing from the side of the semiconductor device toward the side of the insulating layer.
